(19) United States
(12) Patent Application Publication
(10) Pub. No.: US 2022/0171244 A1
(43) Pub. Date: Jun. 2, 2022

(54) ARRAY SUBSTRATE, DISPLAY PANEL AND DISPLAY DEVICE

(71) Applicants: Fuzhou BOE Optoelectronics Technology Co., Ltd., Fuzhou (CN); BOE TECHNOLOGY GROUP CO., LTD., Beijing (CN)

(72) Inventors: Shanshan Xu, Beijing (CN); Xu Xu, Beijing (CN); Wenli Fan, Beijing (CN); Jianfu Pan, Beijing (CN); Xin Fang, Beijing (CN)

(21) Appl. No.: 17/488,499

(22) Filed: Sep. 29, 2021

(30) Foreign Application Priority Data
Nov. 27, 2020 (CN) 202011359179.1

(51) Int. Cl. G02F 1/1362; G02F 1/1343; G02F 1/1368; H01L 27/12

(52) U.S. Cl. CPC G02F 1/136286; H01L 27/124; G02F 1/1368; G02F 1/134372

(57) ABSTRACT

The present disclosure provides an array substrate, a display panel, and a display device. The array substrate includes a substrate, pixel units arranged in rows and columns on the substrate, and data lines between at least some columns of pixel units. Two columns of pixel units are disposed between two adjacent data lines. Each of the pixel units includes a first electrode including a planar electrode and a second electrode including a slit electrode having at least one slit, sequentially disposed on the substrate. The slit electrode of each of the pixel units has a first side proximal to a data line nearest to the slit electrode and a second side distal to the data line nearest to the slit electrode, opposite to each other in a row direction. The slit electrode of at least one of the pixel units includes at least one opening on the first side.

### CROSS-REFERENCE TO RELATED APPLICATION

The present application claims priority from Chinese patent application No. 202011359179.1 filed on Nov. 27, 2020, the entirety of which is incorporated herein by reference.

### TECHNICAL FIELD

The present disclosure relates to the field of display technologies, in particular to an array substrate, a display panel, and a display device.

### BACKGROUND

Currently, liquid crystal display panels mainly include Twisted Nematic (TN) type liquid crystal display panels, Vertical Alignment (VA) type liquid crystal display panels, In-Plane Switching (IPS) type liquid crystal display panels, and Advanced Super Dimension Switch (ADS) type liquid crystal display panels. The ADS type liquid crystal display panels have advantages of high resolution, high transmittance, low power consumption, wide viewing angle, high aperture ratio, and the like, and thus are sought after in the market. However, the current liquid crystal display panels with high resolution or large size have problems such as difficulty in charging, low charging rate, and low light efficiency, which affect the display effect.

### SUMMARY

Embodiments of the present disclosure provide an array substrate, including:

a substrate;

a plurality of pixel units arranged in a plurality of rows and a plurality of columns on the substrate; and

data lines between at least some columns of pixel units of the plurality of columns of pixel units, two columns of pixel units being disposed between two adjacent data lines,

wherein each of the plurality of pixel units includes a first electrode and a second electrode sequentially disposed on the substrate, the first electrode includes a planar electrode, and the second electrode includes a slit electrode having at least one slit,

the slit electrode of each of the plurality of pixel units has a first side and a second side opposite to each other in a row direction, the first side is a side of the slit electrode proximal to a data line nearest to the slit electrode, and the second side is a side of the slit electrode distal to the data line nearest to the slit electrode, and

the slit electrode of at least one of the plurality of pixel units includes at least one opening on the first side.

In some embodiments, the opening of the slit electrode corresponds to the slit of the slit electrode, and the opening is in communication with the corresponding slit.

In some embodiments, the slit electrode includes a plurality of openings and a plurality of slits, the plurality of openings have a one-to-one correspondence with the plurality of slits, and each of the plurality of openings is in communication with the corresponding slit, such that the slit electrode has a comb structure.

In some embodiments, the array substrate further includes common signal lines between at least some columns of pixel units of the plurality of columns of pixel units, two columns of pixel units being disposed between two adjacent common signal lines,

wherein the common signal lines are alternately arranged with the data lines, and one column of pixel units is disposed between the common signal line and the data line adjacent to each other.

In some embodiments, each of the data lines corresponds to two columns of pixel units near the data line and is coupled to the slit electrodes of the two columns of pixel units near the data line, and the common signal lines are coupled to the planar electrodes of the plurality of pixel units.

In some embodiments, each of the data lines is coupled to the slit electrodes of two columns of pixel units closest to the data line among pixel units on a same side of the data line in the row direction.

In some embodiments, each row of pixel units of at least some rows of pixel units of the plurality of rows of pixel units is coupled to a first gate line, a second gate line, and a plurality of groups of transistors, the first gate line, the second gate line, and the plurality of groups of transistors are included in the array substrate, and the first gate line and the second gate line are respectively on two opposite sides of the row of pixel units in a column direction, the first gate line is between the row of pixel units and one row of pixel units that is adjacent to the row of pixel units, the second gate line is between the row of pixel units and the other row of pixel units that is adjacent to the row of pixel units, and the first gate line and the second gate line are not coupled to other rows of pixel units, and

each group of transistors of the plurality of groups of transistors includes a first transistor and a second transistor, a control electrode of the first transistor is coupled to one of the first gate line and the second gate line, a control electrode of the second transistor is coupled to the other one of the first gate line and the second gate line, a first electrode of the first transistor and a first electrode of the second transistor are coupled to a same data line, a second electrode of the first transistor is coupled to the slit electrode of one of two pixel units, included in two columns of pixel units corresponding to the same data line, of the row of pixel units, and a second electrode of the second transistor is coupled to the slit electrode of the other one of the two pixel units, included in the two columns of pixel units corresponding to the same data line, of the row of pixel units.

In some embodiments, the slit electrode of at least one of the plurality of pixel units includes a first pixel region and a second pixel region adjacent to each other in the column direction, the slit electrode includes a plurality of slits in the first pixel region that are parallel to each other and extend in a first direction, the slit electrode includes a plurality of slits in the second pixel region that are parallel to each other and extend in a second direction, and the first direction is different from the second direction.

In some embodiments, the plurality of slits in the first pixel region have a same width, and the plurality of slits in the second pixel region have a same width.

In some embodiments, each of the data lines corresponds to two columns of pixel units near the data line and is coupled to the planar electrodes of the two columns of pixel units near the data line, and the common signal lines are coupled to the slit electrodes of the plurality of pixel units.

In some embodiments, the opening of the slit electrode is not in communication with the slit of the slit electrode.

In some embodiments, the slit electrode includes a plurality of openings and a plurality of slits, and at least one of the plurality of openings is not in communication with the plurality of slits.

Embodiments of the present disclosure further provide a display panel, including: the array substrate described above, a color filter substrate opposite to the array substrate, and a liquid crystal layer between the array substrate and the color filter substrate.

Embodiments of the present disclosure further provide a display device including the display panel described above.

### BRIEF DESCRIPTION OF THE DRAWINGS

FIG. 1 illustrates a schematic plan view of an array substrate according to a comparative example;

FIG. 2 illustrates a schematic plan view of an array substrate according to an embodiment of the present disclosure; and

FIG. 3 illustrates a schematic cross-sectional view of the array substrate of FIG. 2 taken along line I-I′.

### DETAILED DESCRIPTION

In order that those skilled in the art will better understand technical solutions of the present disclosure, the present disclosure will be further described in detail below with reference to accompanying drawings and specific embodiments.

Unless defined otherwise, technical or scientific terms used herein shall have the ordinary meaning as understood by those skilled in the art to which this disclosure belongs. The terms “first”, “second”, and the like used in the present disclosure are not intended to indicate any order, quantity, or importance, and are only used to distinguish different components. Also, the terms “a”, “an”, “the”, and the like are not intended to limit quantity, and are only used to indicate the presence of at least one. The word “comprise”, “include”, or the like means that the element(s) or item(s) that appears before the word covers the element(s) or item(s) that appears after the word and its equivalents, and other elements or items are not excluded. Words such as “connected”, “coupled”, and the like are not restricted to physical or mechanical connections, and may include direct or indirect electrical connections. The terms “upper”, “lower”, “left”, “right”, and the like are only used to indicate relative positional relationships, and when the absolute position of the object being described is changed, the relative positional relationships may also be changed accordingly. “One element” being disposed on “another element” may mean that the “one element” is directly on the “other element” or there is an intermediate element between the “one element” and the “other element”.

It should be noted that transistors in embodiments of the present disclosure may include a thin film transistor, a field effect transistor, or other devices with similar functions. Since the source and the drain of the transistor in the embodiments of the present disclosure are symmetrical, there is no difference between the source and the drain. In the embodiments of the present disclosure, in order to distinguish the source and the drain of the transistor, one of them is referred to as a first electrode and the other one is referred to as a second electrode, and the gate of the transistor is referred to as a control electrode. In addition, the transistors may be classified as N-type transistors or P-type transistors according to property of the transistors. In the following examples, the N-type transistor is used for illustration. For example, when the N-type transistor is used in the embodiments of the present disclosure, the first electrode is the source of the N-type transistor, the second electrode is the drain of the N-type transistor, and when a high level is input to the gate of the N-type transistor, the N-type transistor is turned on. The property of the P-type transistor is opposite to that of the N-type transistor. The implementation of the embodiments of the present disclosure using P-type transistors can be easily conceived by those skilled in the art without creative work, and therefore it is also within the protection scope of the embodiments of the present disclosure.

Current liquid crystal display panels tend to have a higher resolution and a larger size. Therefore, in order to drive more pixel units to emit light, a large number of data lines need to be provided. However, the bonding of a large number of data lines to a flexible circuit board located in the bezel of the liquid crystal display panel may cause the liquid crystal display panel to have a wider bezel, which is disadvantageous to the full-screen display of the liquid crystal display panel. In order to reduce the number of data lines, dual gate driving is generally used to drive the liquid crystal display panel, that is, two gate lines are used to control and drive pixel units in different columns in a same row of pixel units, respectively, and the number of data lines used for driving the pixel units to emit light is half of the number of data lines required by a conventional driving method, so that the number of data lines can be reduced by half. However, the reduction of the number of data lines may increase the loading on the data lines, which may cause the problems such as difficulty in charging, low charging rate, and low light efficiency, and affect the display effect.

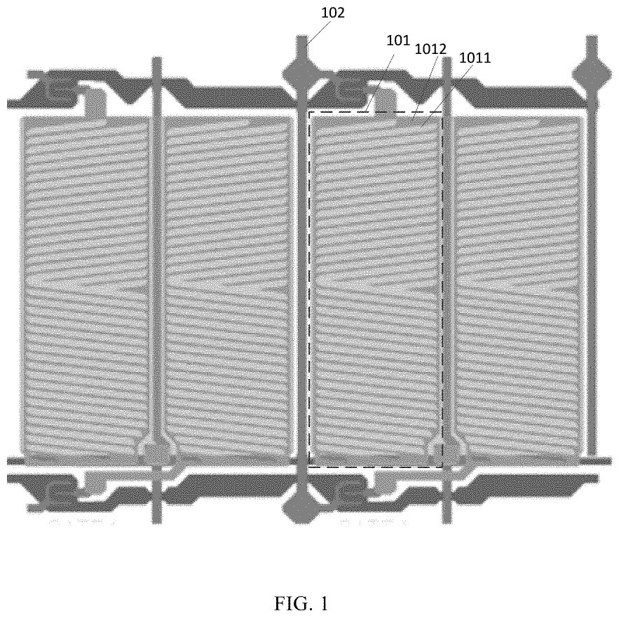

FIG. 1 illustrates a schematic plan view of an array substrate according to a comparative example.

As shown in FIG. 1, the array substrate includes a substrate (not shown), a plurality of pixel units 101 arranged in rows and columns on the substrate, and data lines 102 disposed between some columns of pixel units 101. Two columns of pixel units 101 are disposed between two adjacent data lines 102. Each pixel unit 101 includes a first electrode 1011 and a second electrode 1012 sequentially disposed on the substrate, the first electrode 1011 may be a planar electrode, the second electrode 1012 may be a slit electrode, and a fringe electric field may be formed between the edge of the slit of the slit electrode and the planar electrode to drive liquid crystal molecules in the liquid crystal layer to be deflected, so as to realize a display function. It is to be understood that unlike the above case, the first electrode may be a slit electrode and the second electrode may be a planar electrode. The loading on the data line 102, i.e., the voltage input to the data line 102, is large and constantly changes. Since a coupling capacitance is easily formed by the data line 102 and the slit electrode and a storage capacitance is easily formed by the slit electrode and the planar electrode, the loading of the data line 102 is further increased. Therefore, the array substrate may have problems such as difficulty in charging, low charging rate, and low light efficiency.

An array substrate, a display panel, and a display device provided by the present disclosure will be described in further detail below in conjunction with the accompanying drawings and specific embodiments.

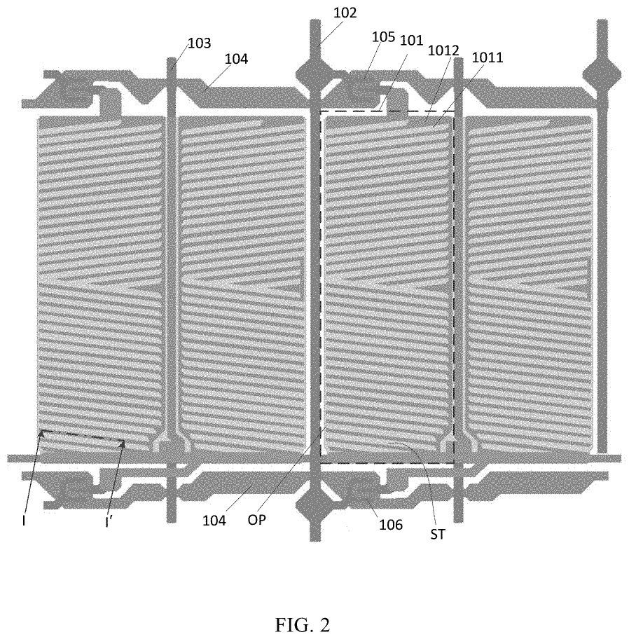

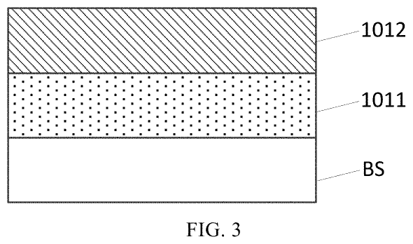

FIG. 2 illustrates a schematic plan view of an array substrate according to an embodiment of the present disclosure. FIG. 3 illustrates a schematic cross-sectional view of the array substrate of FIG. 2 taken along line I-I′.

As shown in FIGS. 2 and 3, the array substrate according to an embodiment of the present disclosure includes: a substrate BS, a plurality of pixel units 101 arranged in a plurality of rows and a plurality of columns on the substrate BS, and data lines 102 between at least some columns of pixel units 101 of the plurality of columns of pixel units 101. Two columns of pixel units 101 are disposed between two adjacent data lines 102. Each of the plurality of pixel units 101 includes a first electrode 1011 and a second electrode 1012 sequentially disposed on the substrate BS, the first electrode 1011 includes a planar electrode, and the second electrode 1012 includes a slit electrode having at least one slit ST. FIG. 2 shows a portion of the planar electrode exposed from the slit ST. The slit electrode of each of the plurality of pixel units 101 has a first side and a second side opposite to each other in a row direction, the first side is a side of the slit electrode proximal to a data line 102 nearest to the slit electrode, and the second side is a side of the slit electrode distal to the data line 102 nearest to the slit electrode. The slit electrode of at least one of the plurality of pixel units 101 includes at least one opening OP on the first side.

In some embodiments, the slit electrode includes a plurality of openings OP. In some embodiments, the slit electrode includes a plurality of slits ST. In the array substrate according to an embodiment of the present disclosure, the opening OP may be disposed at an edge of the slit electrode and exposed to the outside of the slit electrode.

In some embodiments, every two adjacent data lines 102 are separated by two columns of pixel units 101.

In the array substrate according to the embodiments of the present disclosure, since the slit electrode includes the opening on the first side, an overlap area between the slit electrode and the planar electrode can be reduced. The reduction of the overlap area between the slit electrode and the planar electrode can reduce a storage capacitance formed by the slit electrode and the planar electrode, so that the loading on the data lines 102 can be reduced, and further, the problems such as difficulty in charging and low charging rate due to the overlarge loading on the data lines 102 can be avoided.

In addition, the opening of the slit electrode of the pixel unit 101 being provided on the first side can reduce the shielding of light by the edge of the pixel unit 101, and accordingly, a dark field area of the array substrate can be reduced, and light transmittance and light efficiency of the array substrate can be improved. Therefore, the display effect can be improved.

For example, in some embodiments, after experimental tests, in the array substrate shown in FIG. 1, a width of the dark field area between two columns of pixel units adjacent to the data line 102 is about 16.48 micrometers, and in the array substrate shown in FIG. 2 according to an embodiment of the present disclosure, the width of the dark field area between two columns of pixel units adjacent to the data line 102 is about 11.72 micrometers. It can be seen that the dark field area of the array substrate according to the embodiment of the present disclosure is significantly reduced.

In some embodiments, the at least one pixel unit 101 including the opening OP is adjacent to the data line 102.

In some embodiments, the slit electrodes of some of the plurality of pixel units 101 each includes the opening OP on the first side, and at least one of the pixel units 101 each including the opening OP is adjacent to the data line 102.

In some embodiments, the slit electrode of each of the plurality of pixel units 101 includes the opening OP on the first side.

Since the slit electrode of the pixel unit 101 adjacent to the data line 102 includes the opening on the first side, an overlap area between the slit electrode and the data line 102 can be reduced. The reduction of the overlap area between the slit electrode and the data line 102 can reduce a coupling capacitance formed by the slit electrode and the data line 102, so that the loading on the data line 102 can be further reduced, and further, the problems such as difficulty in charging and low charging rate due to the overlarge loading on the data line 102 can be avoided.

In some embodiments, as shown in FIG. 2, the opening OP of the slit electrode corresponds to the slit ST of the slit electrode, and the opening OP is in communication with the corresponding the slit ST. In this case, the slit ST of the slit electrode is exposed to the outside of the slit electrode through the corresponding opening OP.

In some embodiments, as shown in FIG. 2, the plurality of openings OP included in the slit electrode are all on the same side, e.g., the first side proximal to the data line 102. In some embodiments, as shown in FIG. 2, the plurality of openings OP may be disposed at an edge of the slit electrode on the first side proximal to the data line 102, the plurality of openings OP of the slit electrode have a one-to-one correspondence with a plurality of slits ST included in the slit electrode, and each opening OP is in communication with the corresponding slit ST, such that the slit electrode is formed to have a comb structure. The slit electrode including the plurality of openings can reduce the overlap area between the slit electrode and the planar electrode to reduce the storage capacitance formed by the slit electrode and the planar electrode, and can reduce the overlap area between the slit electrode and the data line 102 to reduce the coupling capacitance formed by the slit electrode and the data line 102.

In some embodiments, the opening of the slit electrode may not be in communication with the slit of the slit electrode. In some embodiments, the slit electrode includes a plurality of openings and a plurality of slits, and at least one of the plurality of openings is not in communication with the plurality of slits. In this case, there may be a one-to-one correspondence between the plurality of openings and the plurality of slits.

In the embodiments of the present disclosure, the openings of the slit electrode are all on the same side of the slit electrode, but the present disclosure is not limited thereto. For example, in some embodiments, the slit electrode may be provided with openings on both the first side and the second side, the openings on the first side and the second side of the slit electrode may have a one-to-one correspondence with the slits of the slit electrode, each opening is in communication with the corresponding slit, and the openings on the first side of the slit electrode may correspond to different slits from the openings on the second side of the slit electrode. For example, in some embodiments, the slits corresponding to the openings on the first side of the slit electrode may be alternately arranged with the slits corresponding to the openings on the second side of the slit electrode (in this case, two adjacent ones of the slits corresponding to the openings on the first side of the slit electrode are separated by one slit corresponding to an opening on the second side of the slit electrode, and two adjacent ones of the slits corresponding to the openings on the second side of the slit electrode are separated by one slit corresponding to an opening on the first side of the slit electrode), such that the slit electrode is formed to have a zigzag structure.

In some embodiments, as shown in FIG. 2, the array substrate according to an embodiment of the present disclosure further includes common signal lines 103 between at least some columns of pixel units 101 of the plurality of columns of pixel units 101, and two columns of pixel units 101 are disposed between two adjacent common signal lines 103. The common signal lines 103 are alternately arranged with the data lines 102, and one column of pixel units 101 is disposed between the common signal line 103 and the data line 102 adjacent to each other.

In some embodiments, as shown in FIG. 2, each of the data lines 102 corresponds to two columns of pixel units 101 near the data line 102 and is coupled to the slit electrodes of the two columns of pixel units 101 near the data line 102, to provide data signals to the two columns of pixel units 101 near the data line 102, and the common signal lines 103 are coupled to and provide common signals to the planar electrodes of the plurality of pixel units 101. In this configuration, since one data line 102 can be controlled to supply data signals to the two columns of pixel units 101 coupled thereto, respectively, at different times, the number of data lines 102 can be reduced by half compared to a case where each column of pixel units requires a separate data line. Since the common signal line 103 and the data line 102 adjacent to each other are separated by one column of pixel units 101, the data line 102 and the common signal line 103 adjacent to each other can be prevented from generating a coupling capacitance and thereby affecting the charging rate of the pixel units 101.

In some embodiments, as shown in FIG. 2, the data line 102 is coupled to and supplies data signals to the slit electrodes of two columns of pixel units 101 closest to the data line 102 among the pixel units 101 on a right side of the data line 102, but the present disclosure is not limited thereto. For example, in some embodiments, the data line 102 may be coupled to and supply data signals to the slit electrodes of two columns of pixel units 101 closest to the data line 102 among the pixel units 101 on a left side of the data line 102. In some embodiments, the data line 102 may be coupled to and supply data signals to the slit electrodes of two columns of pixel units 101 adjacent to the data line 102.

In the configuration shown in FIG. 2, the slit electrode is a pixel electrode, the planar electrode is a common electrode, data signals may be supplied to the pixel electrodes through the data lines 102, and common signals may be supplied to the common electrodes through the common signal lines 103, such that a fringe electric field may be generated between the edge of the slit of the slit electrode and the planar electrode to drive liquid crystal molecules in the liquid crystal layer to be deflected in an ADS drive mode, so as to realize a display function of a liquid crystal display panel.

In some embodiments, each of the data lines 102 is coupled to the planar electrodes of the two columns of pixel units 101 near the data line 102, and the common signal lines 103 are coupled to the slit electrodes of the plurality of pixel units 101. In this case, the planar electrode is a pixel electrode, the slit electrode is a common electrode, data signals may be supplied to the pixel electrodes through the data lines 102, and common signals may be supplied to the common electrodes through the common signal lines 103, such that a fringe electric field may be generated between the edge of the slit of the slit electrode and the planar electrode to drive liquid crystal molecules in the liquid crystal layer to be deflected in an ADS drive mode, so as to realize a display function of a liquid crystal display panel.

In some embodiments, as shown in FIG. 2, each row of pixel units 101 of at least some rows of pixel units 101 of the plurality of rows of pixel units 101 is coupled to two gate lines 104 (for example, a first gate line and a second gate line) and a plurality of groups of transistors. The two gate lines 104 and the plurality of groups of transistors are included in the array substrate according to an embodiment of the present disclosure. The first gate line and the second gate line are respectively on two opposite sides of the row of pixel units 101 in a column direction, the first gate line is between the row of pixel units 101 and one row of pixel units 101 that is adjacent to the row of pixel units 101, the second gate line is between the row of pixel units 101 and the other row of pixel units 101 that is adjacent to the row of pixel units 101, and the first gate line and the second gate line are not coupled to other rows of pixel units. Each group of transistors of the plurality of groups of transistors includes a first transistor 105 and a second transistor 106, a gate of the first transistor 105 is coupled to one of the two gate lines 104, a gate of the second transistor 106 is coupled to the other one of the two gate lines 104, a source of the first transistor 105 and a source of the second transistor 106 are coupled to a same data line 102, a drain of the first transistor 105 is coupled to the slit electrode of one of two pixel units 101, included in two columns of pixel units 101 corresponding to the same data line 102, of the row of pixel units 101, and a drain of the second transistor 106 is coupled to the slit electrode of the other one of the two pixel units 101, included in the two columns of pixel units 101 corresponding to the same data line 102, of the row of pixel units 101.

In this case, in some embodiments, as shown in FIG. 2, when scanning one row of pixel units coupled to two gate lines 104, at a first time, a high-level scanning signal may be input to the first gate line of the two gate lines 104 to turn on a first transistor 105 coupled to the first gate line, a data signal may be supplied to the slit electrode of a pixel unit 101 coupled to the turned-on first transistor 105 through the data line 102 coupled to the turned-on first transistor 105 and the turned-on first transistor 105, and a common signal may be supplied to the planar electrode of the pixel unit 101 through the common signal line 103, such that an fringe electric field may be generated between the edge of the slit of the slit electrode and the planar electrode to drive liquid crystal molecules in the liquid crystal layer to be deflected. At a second time different from the first time, a scanning signal may be input into the second gate line of the two gate lines 104 to turn on a second transistor 106 coupled to the second gate line to supply a data signal to the slit electrode of a pixel unit 101 coupled to the turned-on second transistor 106. Each row of pixel units 101 may be scanned to implement a display function. It can be seen that one row of pixel units 101 may be controlled by more than one gate line 104, such that the pixel units 101 in a same row are driven at different times, and thus the number of data lines 102 can be reduced at least by half.

In the embodiments of the present disclosure, each row of pixel units 101 of at least some rows of pixel units 101 of the plurality of rows of pixel units 101 is coupled to a separate first gate line, a separate second gate line, and a separate plurality of groups of transistors.

In some embodiments, each row of pixel units 101 of the plurality of rows of pixel units 101 is coupled to a separate first gate line, a separate second gate line, and a separate plurality of groups of transistors.

In some embodiments, as shown in FIG. 2, the slit electrode of at least one of the plurality of pixel units 101 includes a first pixel region and a second pixel region adjacent to each other in the column direction, the slit electrode includes a plurality of slits in the first pixel region that are parallel to each other and extend in a first direction, the slit electrode includes a plurality of slits in the second pixel region that are parallel to each other and extend in a second direction, and the first direction is different from the second direction.

It is understood that the angle between the first direction and the second direction may be set as required. Data signals in the first pixel region and the second pixel region may be controlled separately, such that the liquid crystal molecules driven by the fringe electric field generated in the first pixel region and the liquid crystal molecules driven by the fringe electric field generated in the second pixel region are respectively deflected in different directions. Therefore, compared to a case where all the slits included in the slit electrode extend in a same direction, the color shift can be effectively reduced, and the display screen can have a larger viewing angle, thereby improving the display effect.

In some embodiments, the plurality of slits in the first pixel region have a same width, and the plurality of slits in the second pixel region have a same width.

It should be noted that the same width of the slits in one pixel region (e.g., the first pixel region or the second pixel region) can ensure that the liquid crystal molecules driven by the fringe electric field generated in the one pixel region are deflected at the same angle, and thus the liquid crystal molecules driven by the fringe electric field generated in the one pixel region are arranged uniformly, orderly and regularly, thereby improving the display uniformity.

In the embodiments of the present disclosure, the slit electrode includes the first pixel region and the second pixel region adjacent to each other, but the present disclosure is not limited thereto. For example, in some embodiments, all of the slits included in the slit electrode are parallel to each other and extend in the same direction.

An embodiment of the present disclosure also provides a display panel including: the array substrate provided in any of the above embodiments, a color filter substrate opposite to the array substrate, and a liquid crystal layer between the array substrate and the color filter substrate.

In the display panel according to the embodiments of the present disclosure, an electric field formed by the array substrate may drive liquid crystal molecules in the liquid crystal layer to be deflected to transmit light, and then the light is filtered to have different colors through the color filter substrate, thereby implementing color display. The slit electrode of each of the plurality of pixel units included in the array substrate has a first side and a second side opposite to each other in a row direction, the first side is a side of the slit electrode proximal to a data line nearest to the slit electrode, and the second side is a side of the slit electrode distal to the data line nearest to the slit electrode. The slit electrode of at least one of the plurality of pixel units includes at least one opening on the first side.

Since the slit electrode includes the opening on the first side, an overlap area between the slit electrode and the planar electrode can be reduced. The reduction of the overlap area between the slit electrode and the planar electrode can reduce a storage capacitance formed by the slit electrode and the planar electrode, so that the loading on the data lines can be reduced, and further, the problems such as difficulty in charging and low charging rate due to the overlarge loading on the data lines can be avoided.

In addition, the opening of the slit electrode of the pixel unit being provided on the first side can reduce the shielding of light by the edge of the pixel unit, and accordingly, a dark field area of the array substrate can be reduced, and light transmittance and light efficiency of the array substrate can be improved. Therefore, the display effect can be improved.

For example, in some embodiments, after experimental tests, in the array substrate shown in FIG. 1, a width of the dark field area between two columns of pixel units adjacent to the data line is about 16.48 micrometers, and in the array substrate shown in FIG. 2 according to an embodiment of the present disclosure, the width of the dark field area between two columns of pixel units adjacent to the data line is about 11.72 micrometers. It can be seen that the dark field area of the array substrate according to the embodiment of the present disclosure is significantly reduced.

An embodiment of the present disclosure also provides a display device including the display panel provided in any of the above embodiments. The display device according to the embodiments of the present disclosure may include a mobile phone, a tablet computer, a smart television, a tablet computer, and the like.

It will be appreciated that the above embodiments are merely exemplary embodiments for the purpose of illustrating the principle of the disclosure, and the disclosure is not limited thereto. Various modifications and improvements can be made by a person having ordinary skill in the art without departing from the spirit and essence of the disclosure. Accordingly, all of the modifications and improvements also fall into the protection scope of the disclosure.

What is claimed is:

1. An array substrate, comprising:
a substrate;
a plurality of pixel units arranged in a plurality of rows and a plurality of columns on the substrate; and
data lines between at least some columns of pixel units of the plurality of columns of pixel units, two columns of pixel units being disposed between two adjacent data lines,
wherein each of the plurality of pixel units comprises a first electrode and a second electrode sequentially disposed on the substrate, the first electrode comprises a planar electrode, and the second electrode comprises a slit electrode having at least one slit,
the slit electrode of each of the plurality of pixel units has a first side and a second side opposite to each other in a row direction, the first side is a side of the slit electrode proximal to a data line nearest to the slit electrode, and the second side is a side of the slit electrode distal to the data line nearest to the slit electrode, and
the slit electrode of at least one of the plurality of pixel units comprises at least one opening on the first side.

2. The array substrate of claim 1, wherein the opening of the slit electrode corresponds to the slit of the slit electrode, and the opening is in communication with the corresponding slit.

3. The array substrate of claim 2, wherein the slit electrode comprises a plurality of openings and a plurality of slits, the plurality of openings have a one-to-one correspondence with the plurality of slits, and each of the plurality of openings is in communication with the corresponding slit, such that the slit electrode has a comb structure.

4. The array substrate of claim 3, further comprising common signal lines between at least some columns of pixel units of the plurality of columns of pixel units, two columns of pixel units being disposed between two adjacent common signal lines,
wherein the common signal lines are alternately arranged with the data lines, and one column of pixel units is disposed between the common signal line and the data line adjacent to each other.

5. The array substrate of claim 4, wherein each of the data lines corresponds to two columns of pixel units near the data line and is coupled to the slit electrodes of the two columns of pixel units near the data line, and the common signal lines are coupled to the planar electrodes of the plurality of pixel units.

6. The array substrate of claim 5, wherein each of the data lines is coupled to the slit electrodes of two columns of pixel units closest to the data line among pixel units on a same side of the data line in the row direction.

7. The array substrate of claim 5, wherein each row of pixel units of at least some rows of pixel units of the plurality of rows of pixel units is coupled to a first gate line, a second gate line, and a plurality of groups of transistors, the first gate line, the second gate line, and the plurality of groups of transistors are comprised in the array substrate, and the first gate line and the second gate line are respectively on two opposite sides of the row of pixel units in a column direction, the first gate line is between the row of pixel units and one row of pixel units that is adjacent to the row of pixel units, the second gate line is between the row of pixel units and the other row of pixel units that is adjacent to the row of pixel units, and the first gate line and the second gate line are not coupled to other rows of pixel units, and
each group of transistors of the plurality of groups of transistors comprises a first transistor and a second transistor, a control electrode of the first transistor is coupled to one of the first gate line and the second gate line, a control electrode of the second transistor is coupled to the other one of the first gate line and the second gate line, a first electrode of the first transistor and a first electrode of the second transistor are coupled to a same data line, a second electrode of the first transistor is coupled to the slit electrode of one of two pixel units, comprised in two columns of pixel units corresponding to the same data line, of the row of pixel units, and a second electrode of the second transistor is coupled to the slit electrode of the other one of the two pixel units, comprised in the two columns of pixel units corresponding to the same data line, of the row of pixel units.

8. The array substrate of claim 7, wherein the slit electrode of at least one of the plurality of pixel units comprises a first pixel region and a second pixel region adjacent to each other in the column direction, the slit electrode comprises a plurality of slits in the first pixel region that are parallel to each other and extend in a first direction, the slit electrode comprises a plurality of slits in the second pixel region that are parallel to each other and extend in a second direction, and the first direction is different from the second direction.

9. The array substrate of claim 8, wherein the plurality of slits in the first pixel region have a same width, and the plurality of slits in the second pixel region have a same width.

10. The array substrate of claim 4, wherein each of the data lines corresponds to two columns of pixel units near the data line and is coupled to the planar electrodes of the two columns of pixel units near the data line, and the common signal lines are coupled to the slit electrodes of the plurality of pixel units.

11. The array substrate of claim 1, wherein the opening of the slit electrode is not in communication with the slit of the slit electrode.

12. The array substrate of claim 1, wherein the slit electrode comprises a plurality of openings and a plurality of slits, and at least one of the plurality of openings is not in communication with the plurality of slits.

13. A display panel, comprising: the array substrate of claim 1, a color filter substrate opposite to the array substrate, and a liquid crystal layer between the array substrate and the color filter substrate.

14. A display device, comprising the display panel of claim 13.
